(19) United States
(12) Patent Application Publication
(10) Pub. No.: US 2013/0119461 A1
(43) Pub. Date: May 16, 2013

(54) SEMICONDUCTOR DEVICE HAVING A BURIED GATE AND METHOD FOR FORMING THEREOF

(71) Applicant: SK HYNIX INC., Icheon (KR)

(72) Inventors: Jaeyoung KIM, Anyang (KR); Seijin KIM, Suwon (KR)

(73) Assignee: SK HYNIX INC., Icheon (KR)

(21) Appl. No.: 13/650,010

(22) Filed: Oct. 11, 2012

(30) Foreign Application Priority Data
Nov. 14, 2011 (KR) 10-2011-0118464
Jan. 30, 2012 (KR) 10-2012-0009196

(51) Int. Cl. H01L 23/48; H01L 29/78

(52) U.S. Cl. 257/330; 257/288; 257/773; 257/E29.262; 257/E23.01

(57) ABSTRACT

A semiconductor device includes: a first interlayer insulating layer in first and second regions of a semiconductor substrate, a second interlayer insulating layer over the first interlayer insulating layer in first and second regions, a hard mask provided between the first and the second interlayer insulating layers in the second region and not extending to the first region, a first metal contact formed through the second interlayer insulating layer and the hard mask in the second region, and a first storage node contact formed through the first interlayer insulating layer in the first region.

### BACKGROUND OF THE INVENTION

1. Technical Field

Embodiments of the present invention can be applied to a semiconductor device having a buried gate and a method for fabricating the same. However, the present invention is not limited to a semiconductor device having a buried gate, and may also be applicable to a semiconductor device having another gate structure such as, for example, a planar gate, a recess gate, etc. In addition, the present invention may be applicable to a memory device, such as a dynamic random access memory (DRAM), a mobile flash memory, etc., or a non-memory device such as an application process for a mobile device, a controller for a flash memory, etc.

2. Related Art

In a conventional process for fabricating a semiconductor device, individual regions are subject to different processes in order to form different device elements. For example, in a DRAM device, different elements and processes are used in a cell region than are used a peripheral region. However, it may be desirable to reduce total process steps in order to accordingly reduce production costs. To do so, process steps necessary for the different regions may be combined so that a given process can be performed at the same time in the different regions. For example, in a DRAM memory device, a process for forming a storage node contact pattern in a cell region and a process for forming a metal line in the peripheral region can be performed in the same process.

FIG. 1 shows a conventional DRAM device having a buried gate 106 in a cell region 100 of a semiconductor substrate. The semiconductor substrate includes a peripheral region 200.

An active region 102 of the substrate is defined by a device isolation region 104. An insulating layer 130 is formed in the active region. The insulating layer 130 is patterned to form a bit line contact pad 108 and a storage node contact pad 112 each coupled to the active region 102 of the substrate.

The, a bit line 110 coupled to the bit line contact pad 108 is formed in the cell region 100. A peri-gate 206 is formed in the peripheral region 200.

A first interlayer insulating layer (ILD1) 150a with a first thickness t1 is formed over the cell region 100 and the peripheral region 200. The first interlayer insulating layer (ILD1) 150a in the peripheral region 200 is patterned to form first and second peri-metal contacts 210a, 210b. The first peri-metal contact 210a is coupled to the peri-gate 206 and has a height h1. The second peri-metal contact 210b is coupled to the active region 102 of the substrate.

First and second metal lines 220a, 220b are formed over the first interlayer insulating layer 150a in the peripheral region 200 and are coupled to the first and the second peri-metal contacts 210a, 210b, respectively.

A second interlayer insulating layer (ILD2) 150b with a second thickness t2 is formed over the second interlayer insulating layer 150a in the cell region 100 and the peripheral region 200.

The first and the second interlayer insulating layers 150a, 150b in the cell region 100 are patterned to form a storage node contact 120. The storage node contact 120 is coupled to the storage node contact pad 112. The storage node contact 120 has a length K1.

In the conventional device, the first and the second peri-metal lines 220a, 220b are formed in a separate step from that where the storage node contact 120 is formed. Thus, a fabrication process is complicated.

In addition, surfaces of the first and the second peri-metal contacts 210a, 210b are space apart by d1 from a surface of the second interlayer insulating layer (ILD2) 150b, for example, to prevent a coupling current between the first and the second peri-metal contacts 210a, 210b and another element which will be formed in a subsequent step. However, the longer the distance d1 between surfaces of the first and the second peri-metal contacts 210a, 210b and the surface of the second interlayer insulating layer (ILD2) 150b, the longer the length K1 of the storage node contact 120. When the length K1 of the storage node contact 120 increases, that is, an aspect ratio is greater. That is, when the distance h1 is long, an aspect ratio of the second storage node contact 120 is great, and thus it becomes difficult to properly form a contact hole for the second storage node contact 120.

In order to reduce the length K1 of the storage node contact 120, it can be considered to reduce the first thickness t1 of the first interlayer insulating layer (ILD1) 150a. However, when the first thickness t1 of the first interlayer insulating layer (ILD1) 150a, a length h1 of the first peri-metal contact 210a also becomes shorter. In that case, a cross-talk between the peri-gate 206 and the first peri-metal line 220a would be serious.

Thus, it is necessary to form the first peri-metal contact 210a long enough to prevent coupling effect with other conductive elements without increasing the length K1 of the storage node contact 120.

### BRIEF SUMMARY OF THE INVENTION

An embodiment of the present invention provides a method for forming a semiconductor device including: (a) providing a first interlayer insulating layer in a first region and a second region of a semiconductor substrate; (b) patterning the first interlayer insulating layer in the first region to form a first storage node contact; (c) patterning the first interlayer insulating layer in the second region to form a first metal contact coupled to a gate in a second region; (d) selectively providing a hard mask pattern over the first interlayer insulating layer in the second region; (e) providing a second interlayer insulating layer (i) over the first interlayer insulating layer in the first region and (ii) over the hard mask pattern in the second region; (f) patterning the second interlayer insulating layer and the hard mask pattern in the second region to form a second metal contact coupled to the first metal contact; and (g) patterning the second insulating layer in the first region to form a second storage node contact coupled to the first storage node contact.

The steps (f) and (g) are performed simultaneously. A top surface of the second metal contact is substantially at the same level as a top surface of the second storage node contact, and wherein a top surface of the second metal contact is substantially at the same level as a top surface of the second interlayer insulating layer. The steps (f) and (g) are performed under such a condition that the hard mask pattern has an etching rate lower than the second interlayer insulating layer. The hard mask includes plasma enhanced nitride.

The method may further include a step of forming a first gate in the first region. The first gate is any of a buried gate, a recess gate, and a planar gate. The semiconductor device is a dynamic random access memory (DRAM), and the first region is a cell region and the second region is a peripheral region.

The second storage node contact extends down to a level L4 lower than a level L3 to which the second metal contact extends. A step difference exists between an upper surface of the first metal contact in the second region and an upper surface of the first storage node contact in the first region.

The method may further include a step of forming an interlayer insulating pad (i) between the first interlayer insulating layer and the hard mask in the second region and (ii) between the first interlayer insulating layer and the second interlayer insulating layer in the first region. The steps (b) and (g) are performed separately.

The semiconductor device may be any of a dynamic random access memory(DRAM), a resistant random access memory (ReRAM), a ferroelectric random access memory (FeRAM), a phase change RAM (PRAM), a magnetic RAM (MRAM), a spin transfer torque-magnetic RAM (STT-RAM), a zero-capacitor RAM (ZRAM), and a combination thereof

An embodiment of the present invention provides a method for forming a semiconductor device including: (a) providing a first interlayer insulating layer in first and second regions of a semiconductor substrate; (b) selectively providing a hard mask pattern over the first interlayer insulating layer in the second region; (c) providing a second interlayer insulating layer (i) over the first interlayer insulating layer in the first region and (ii) over the hard mask in the second region; (d) patterning the second interlayer insulating layer and the hard mask in the second region to form a first metal contact; and (e) patterning the second insulating layer in the first region to form a first storage node contact.

The steps (d) and (e) are performed simultaneously. A top surface of the first metal contact is substantially at the same level as a top surface of the first storage node contact.

The method may further include a step of forming an interlayer insulating pad (i) under the hard mask in the second region and (ii) under the second interlayer insulating layer in the first region. The first metal contact is coupled to an underlying second metal contact, and the first storage node contact is coupled to an underlying second storage node contact.

An embodiment of the present invention provides a method for forming a semiconductor device including: (a) providing a buried cell gate over a substrate in a cell region; (b) forming an insulating pattern having first and second contact holes in the cell region; (c) filling the first and second contact holes with conductive materials to form a bit line pad and a storage node pad, respectively; (d) forming a first conductive layer over the substrate in a peripheral region; (e) forming a second conductive layer over the insulating pattern in the cell region and over the first conductive layer in the peripheral region; (f) patterning the second conductive layer in the cell region to form a bit line coupled to the bit line pad; (g) patterning the first and the second conductive layers in the peripheral region to form a peri-gate; (h) forming a first interlayer insulating layer in the cell region and the peripheral region to cover the bit line and the peri-gate; (i) patterning the first interlayer insulating layer in the cell region to form first storage node contact coupled to the storage node pad; (j) forming an interlayer insulating pad over the first interlayer insulating layer in the cell region and the peripheral region; (k) pattering the interlayer insulating pad and the first interlayer insulating layer in the peripheral region to form a first peri-metal contact coupled to the peri-gate; (l) forming a hard mask over the first peri-metal contact in the peripheral region, wherein the hard mask does not extend to the peripheral region; (m) forming a second interlayer insulating layer over the first interlayer insulating layer in the cell region, and over the hard mask in the peripheral region; (n) patterning the second interlayer insulating layer and the interlayer insulating pad in the cell region to form a second storage node contact coupled to the first storage node contact; and (o) patterning the second interlayer insulating layer and the hard mask in the peripheral region to form a second peri-metal contact coupled to the first peri-metal contact.

The steps (n) and (o) are performed simultaneously. A top surface of the second peri-metal contact is substantially at the same level as a top surface of the second storage node contact. A top surface of the second peri-metal contact is substantially at the same level as a top surface of the second interlayer insulating layer. The steps (n) and (o) are performed under such a condition that the hard mask has an etching rate lower than that of the second interlayer insulating layer.

An embodiment of the present invention provides a semiconductor device including: a first interlayer insulating layer in first and second regions of a semiconductor substrate; a second interlayer insulating layer over the first interlayer insulating layer in first and second regions; a hard mask provided between the first and the second interlayer insulating layers in the second region and not extending to the first region; a first metal contact formed through the second interlayer insulating layer and the hard mask in the second region; and a first storage node contact formed through the first interlayer insulating layer in the first region.

A top surface of the a first metal contact may be substantially at the same level as a top surface of the first storage node contact. A top surface of the first metal contact may be substantially at the same level as a top of the second interlayer insulating layer. A bottom of the first metal contact may be at a higher level than a bottom of the first storage node contact.

The device may further include: an interlayer insulating pad formed (i) between the first interlayer insulating layer and the hard mask in the second region and (ii) between the first and the second interlayer insulating layers in the first region.

The device may further include: a second metal contact formed through the first interlayer in the second region and coupled to the first metal contact; and a second storage node contact formed through the first interlayer in the first region and coupled to the first storage node contact. The second metal contact is coupled to a gate in the second region. The gate in the second region is a peri-gate in a planar type.

The second metal contact is formed through the interlayer insulating pad in the second region, and a top of the second metal contact is at a higher level than a top of the second storage node contact. The first storage node contact is formed through the interlayer insulating pad. The hard mask pattern has an etch rate different from the interlayer insulating pad.

The device may further include: a first gate formed in the first region. The first gate is any of a buried gate, a recess gate, and a planar gate. The semiconductor device is any of a dynamic random access memory (DRAM), a resistant random access memory (ReRAM), a ferroelectric random access memory (FeRAM), a phase change RAM (PRAM), a magnetic RAM (MRAM), a spin transfer torque-magnetic RAM (STT-RAM), a zero-capacitor RAM (ZRAM), and a combination thereof, and wherein the first region is a cell region and the second region is a peripheral region.

The hard mask pattern includes plasma enhanced nitride. The hard mask pattern has an etch rate different from the first interlayer insulating layer. The first contact and the first metal contact are formed of the same conductive material. The first contact and the first metal contact include tungsten.

An embodiment of the present invention provides a semiconductor device including: a first storage node contact formed in a first region of a semiconductor substrate and extending upward to a first level; a first metal contact formed in a second region of the semiconductor substrate, coupled to a gate in the second region, and extending upward to a second level; a hard mask formed in the second region and not extending to the peripheral region, wherein the hard mask extends from a third level up to a fourth level, wherein the third level is substantially the same as or higher than the second level; a second storage node contact formed in the first region, extending down to a fifth level to be coupled to the first storage node contact, and extending up to a sixth level; and a second metal contact formed in the second region, extending down to a seventh level to be coupled to the first metal contact, and extending up to the sixth level.

The second level is higher than or substantially the same as the first level. The second level and the third level are substantially the same. The seventh level is higher than or substantially the same as the fifth level.

The first storage node and the first metal contact are formed through a first interlayer insulating layer. The second storage node and the second metal contact are formed through a second interlayer insulating layer and the second interlayer insulating layer is provided over the first interlayer insulting layer. The hard mask is formed between the first and the second interlayer insulating layers in the second region and does not extend to the first region. The second metal contact is formed through the hard mask.

The semiconductor device may further include an interlayer insulating pad formed (i) between the first interlayer insulating layer and the hard mask in the second region and (ii) between the first and the second interlayer insulating layers in the first region. The second storage node contact is formed through the interlayer insulating pad in the first region. The first metal contact is formed through the interlayer insulating pad in the second region.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a cross-sectional view of a conventional semiconductor memory device.

FIG. 2 is a plan view of a cell region of a semiconductor device according to a first embodiment of the present invention.

FIG. 2(a)(i) is a cross-sectional view of the semiconductor device, including a cross-sectional view of the cell region taken along the line X-X′ in FIG. 2.

FIG. 2(a)(ii) is a cross-sectional view of the cell region taken along the line Y-Y′ in FIG. 2.

FIGS. 2b-2o are cross-sectional views illustrating a method for fabricating a semiconductor device according to a first embodiment of the present invention.

FIG. 3 is a cross-sectional view illustrating a semiconductor device according to a second embodiment of the present invention.

FIG. 4 is a circuit diagram of a memory cell array according to an embodiment of the present invention.

FIG. 5 is a block diagram that shows a functional unit employing the memory cell array shown in FIG. 4.

FIG. 6 is a block diagram of a memory module employing the module shown in FIG. 5.

FIG. 7 is a block diagram of a memory system employing the module shown in FIG. 6.

### DESCRIPTION OF EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

Since preferred embodiments are provided below, the order of the reference numerals given in the description is not limited thereto. In the drawings, the dimensions of layers and regions may be exaggerated for convenience of illustration. It should be understood that when a layer (or film) is referred to as being “on” another layer or substrate, it can be directly on the other layer or substrate, or intervening layers may also be present.

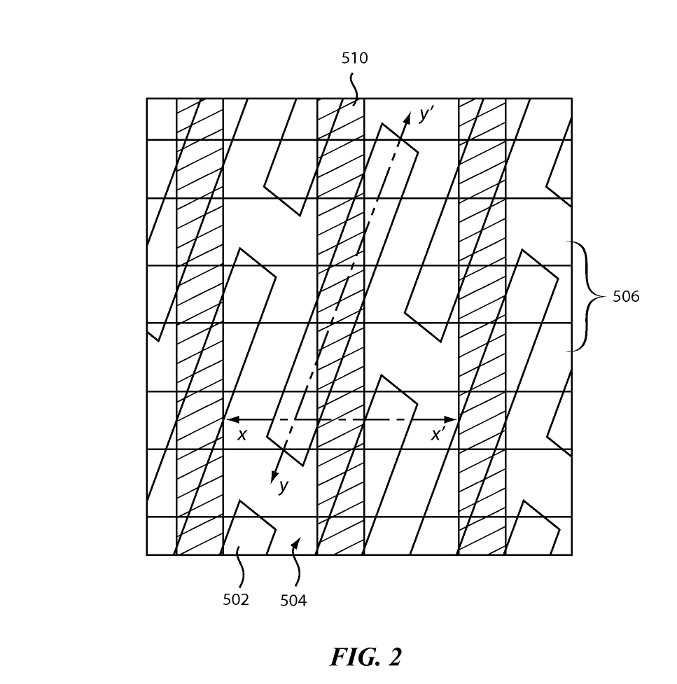

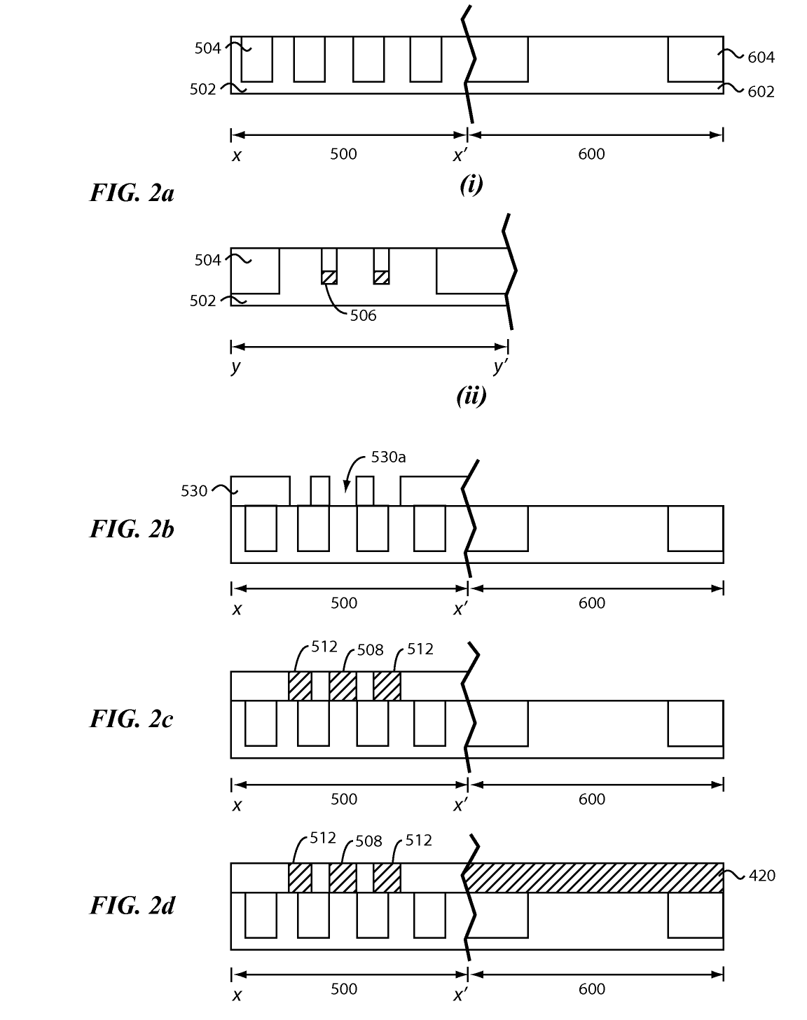

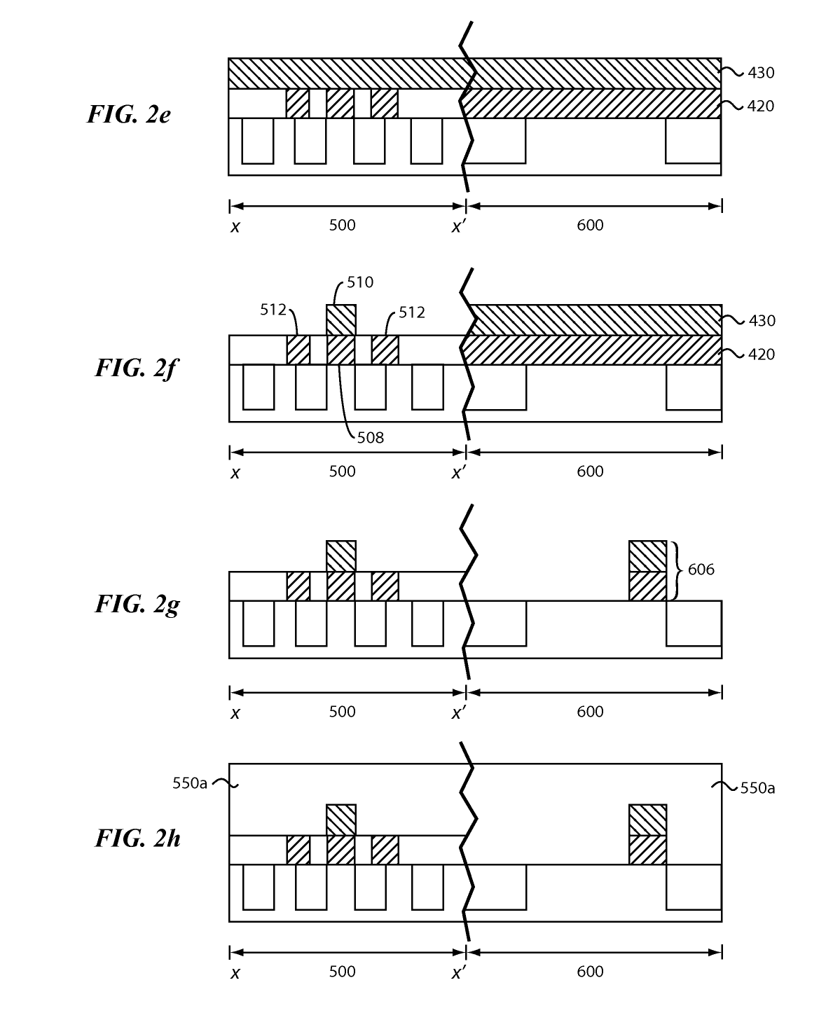

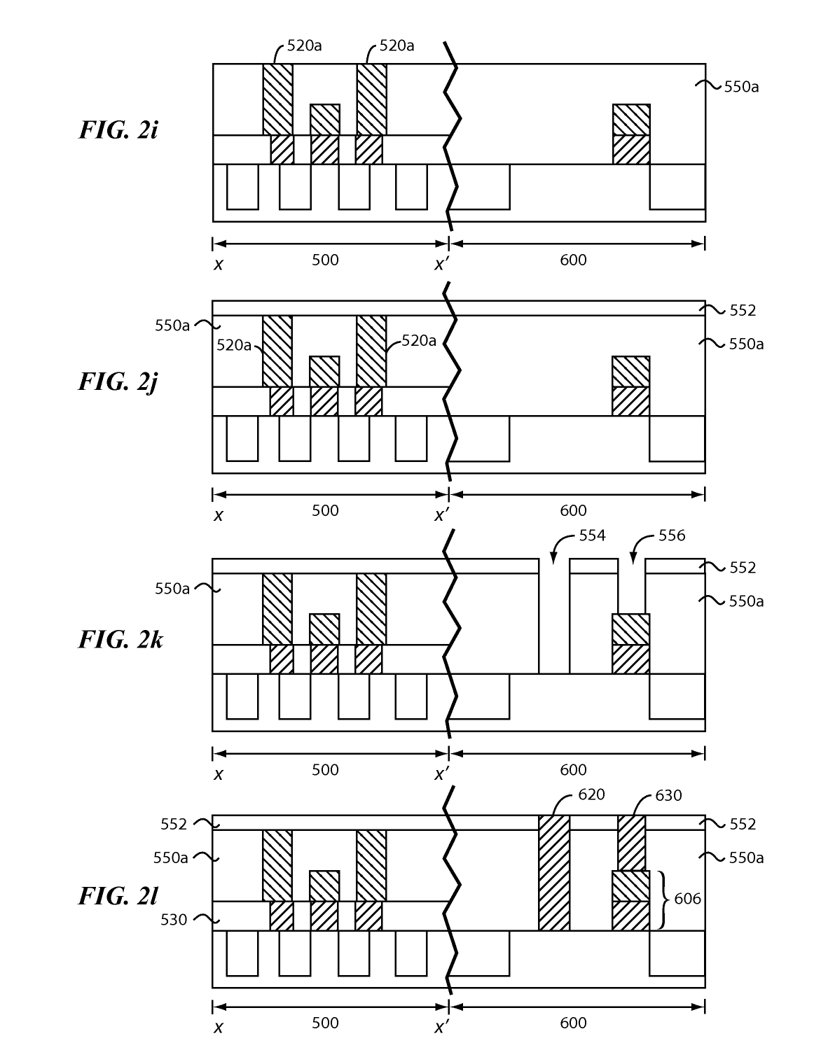

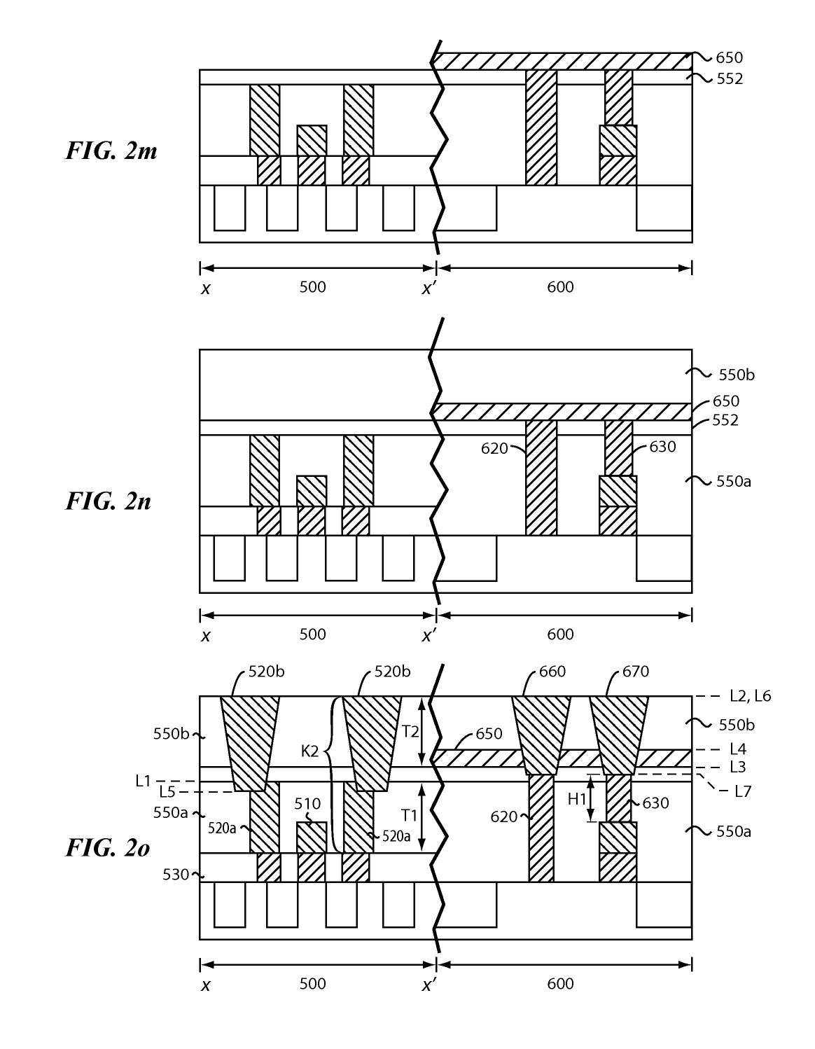

Hereinafter, a method according to a first embodiment of the present invention will be described with reference to FIGS. 2, and 2a(1)-2o.

In FIGS. 2, and 2a, a buried cell gate 506 is formed in a cell region 500 of a substrate. The cell region 500 includes an active region 502 and a device isolation region 504. A peripheral region 600 includes a peri-active region 602 and a peri-device isolation region 604. The cell gate 506 is not limited to a buried gate, and may be replaced with any type of gate including but not limited to a recess gate, a planar gate, etc.

In FIG. 2b, an insulating layer (not shown) is formed over the cell region 500. The insulating layer is patterned to expose the active region 502 where a source/drain region (not shown) are formed, thus forming an insulating pattern 530 having a contact hole 530a exposing the source/drain region.

In FIG. 2c, a conductive fills the contact hole 530a to form a bit line pad 508 and a storage node pad 512. The conductive material forming the bit line pad 508 and the storage node pad 512 can be any conductive material, including but not limited to, a semiconductor material such as a polysilicon, a metal such as tungsten(W), titanium (Ti), and titanium nitride (TiN), a silicide such as SiW, SiTi, SiTiN, etc., and a combination thereof

The process of forming the bit line pad 508 and the storage node pad 512 can be performed in a various way, including but not limited to an etch-back process or a chemical mechanical polishing (CMP) process. For example, a polysilicon layer is formed over the insulating pattern 530 in the cell region 500 to fill the contact hole 530a. Then, the polysilicon layer is subject to a CMP process to expose the insulating pattern 530, thus forming the bit line pad 508 and the storage node pad 512.

In FIG. 2d, a conductive material is formed over the substrate in the peripheral region 600 to form a first conductive layer 420. The first conductive layer 420 is preferred to be planarized so that a top surface in the peripheral region 600 a top surface in the cell region 500. However, the present invention is not limited thereto. That is, a step difference may exist between the top surface in the peripheral region 600 and the top surface in the cell region 500.

The conductive material forming the first conductive layer 420 can be any conductive material, including but not limited to, a semiconductor material such as a polysilicon, a metal such as tungsten(W), titanium (Ti), and titanium nitride (TiN), a silicide such as SiW, SiTi, SiTiN, etc., and a combination thereof

Generally, the conductive material for the first conductive layer 420 is different from the conductive material forming of the bit line pad 508 or the storage node pad 512. Thus, a step for forming the first conductive layer 420 and a step of forming the bit line pad 508 and the storage node pad 512 are performed separately.

However, the conductive material for the first conductive layer 420 may be the same as the conductive material forming of the bit line pad 508 or the storage node pad 512. In that case, the present invention should be understood to include an embodiment where the step for forming the first conductive layer 420 and the step of forming the bit line pad 508 and the storage node pad 512 are performed simultaneously.

In FIG. 2e, a second conductive layer 430 is formed in the cell region 500 and the peripheral region 600. The second conductive layer 430 can be formed of any conductive material, including but not limited to, a semiconductor material such as a polysilicon, a metal such as tungsten(W), titanium (Ti), and titanium nitride (TiN), a silicide such as SiW, SiTi, SiTiN, etc., and a combination thereof

In FIG. 2f, the second conductive layer 430 in the cell region is patterned to form a bit line 510 coupled to the bit line pad 508. The second conductive layer 430 in the peripheral region 600 is patterned to form a second gate layer 440 over the first gate layer 420.

In FIG. 2g, the first and the second gate layers 420, 440 are patterned to form a peri-gate 606.

In FIG. 2h, a first interlayer insulating layer (ILD1) 550a is formed in the cell region 500 and the peripheral region 600. The first interlayer insulating layer (ILD1) 550a may be formed of any insulating material, including but not limited to silicon oxide.

In FIG. 2i, the first interlayer insulating layer 550a in the cell region 500 is patterned to form a contact hole (not shown) exposing the storage node contact pad 512. A conductive material fills the contact hole to form a first storage node contact (SNC1) 520a. The conductive material for the first storage node contact (SNC1) 520a can be formed of any conductive material, including but not limited to, a semiconductor material such as a polysilicon, a metal such as tungsten(W), titanium (Ti), and titanium nitride (TiN), a silicide such as SiW, SiTi, SiTiN, etc., and a combination thereof

In FIG. 2j, an interlayer insulating pad 552 is formed in the cell region 500 and the peripheral region 600. In the cell region 500, the interlayer insulating pad 552 is formed over the first interlayer insulating layer 550a and the firs storage node contact 520. In the peripheral region 600, the interlayer insulating pad 552 is formed over the first interlayer insulating layer 550a. The interlayer insulating pad 552 may be formed of any insulating material, including but not limited to silicon oxide.

In FIG. 2k, the interlayer insulating pad 552 and the first interlayer insulating layer 550a in the peripheral region 600 are patterned to form first and second peri-contact holes 554, 556. The first peri-contact hole 554 exposes the active region 602 of the substrate in the peripheral region and the second peri-contact hole 556 exposes the peri-gate 606.

In FIG. 21, a fourth conductive material fills the first and the second per-contact holes 554, 556 to form first and second metal contacts 620, 630, respectively. The first and the second metal contacts 620, 630 can be formed of any conductive material, including but not limited to, a semiconductor material such as a polysilicon, a metal such as tungsten(W), titanium (Ti), and titanium nitride (TiN), a silicide such as SiW, SiTi, SiTiN, etc., and a combination thereof.

Due to the interlayer insulating pad 552, the first and the second metal contacts 620, 630 in the peripheral region have step differences from the first storage node contact 520a by a thickness of the interlayer insulating pad 552. That is, upper surfaces of the first and the second metal contacts 620, 630 in the peripheral region are formed at a higher level than an upper surface of the first storage node contact 520a.

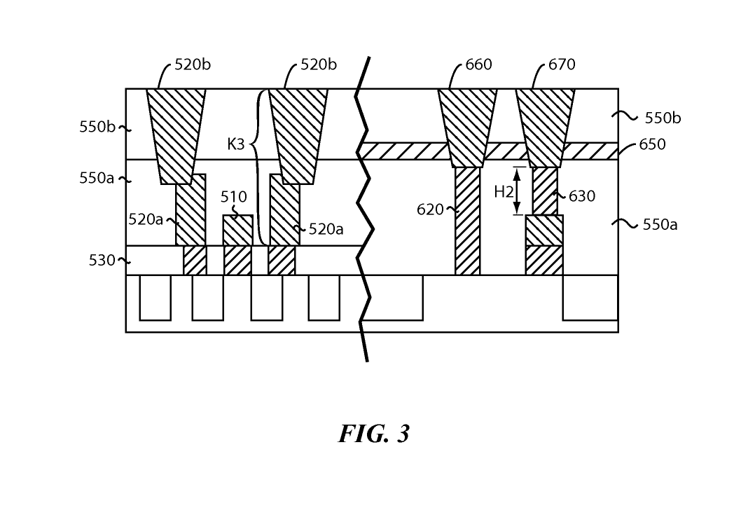

This step difference may create a hydrogen path around a boundary between the cell region and the peripheral region, thus contributing an improvement of reliability of a device. However, as shown in FIG. 3, the step of forming the interlayer insulating pad 552 can be omitted if it is unnecessary to create a separate hydrogen path.

In FIG. 2m, a peri hard mask 650 is selectively formed over the interlayer insulating pad 552 in the peripheral region 600. The term “selectively” means that the peri-hard mask 650 is formed in the peripheral region 600 and not formed in the cell region 500. The peri hard mask 650 may be formed of any insulating material, include but not limited to silicon nitride. It is preferred that the peri-hard mask 650 is formed of plasma enhanced nitride with a thickness of 200˜1000 angstrom. However, the present invention is not limited thereto.

In FIG. 2n, a second interlayer insulating layer 550b is formed in the cell region 500 and the peripheral region 600. In the cell region, the second interlayer insulating layer 550b is formed over the interlayer insulating pad 552. In the peripheral region, the second interlayer insulating layer 550b is formed over the peri-hard mask 650. The second interlayer insulating layer 550b may be formed of any insulating material, include but not limited to silicon oxide. It is desirable that the second interlayer insulating layer 550b has an etch resistance higher than the peri-hard mask 650.

In FIG. 2o, in the cell region, the second interlayer insulating layer 550b and the interlayer insulating pad 552 is patterned to form a contact hole (not shown) exposing the first storage node contact 520a. At the same time, in the peripheral region, the second interlayer insulating layer 550b and the peri-hard mask 650 are pattern to form peri-contact holes (not shown) expose the first and the second metal contacts 620, 630.

A fifth conductive material fills the contact hole exposing the first storage node contact 520a in the cell region to form a second storage node contact 550b. The peri-contact holes (not shown) exposing the first and the metal contacts 620, 630 in the peripheral region 600 are also fills with conductive material to form third and the fourth metal contacts 660, 670.

In FIG. 2o, the patterning condition is adjusted so that the peri-hard mask 650 has a lower etch rate than the second interlayer insulating layer 550b. Under this condition, the second interlayer insulating layer 550b is removed faster than the peri-hard mask 650.

For example, assuming a dry etching process is employed to pattern the second interlayer insulating layer 550b, in the peripheral region, an etching rate slows down at the point when the peri-hard mask 650 is exposed. On the other hand, in the cell region, there is no peri-hard mask 650 is formed. Thus, the second interlayer insulating layer 550b is removed faster than the peri-hard mask 650.

A top surface of fourth metal contact 670 may be formed substantially at the same level L2 as a top surface of the second storage node contact SNC2: 520b. A top surface of the fourth metal contact 670 may be formed substantially at the same level as a top surface of the second interlayer insulating layer 550b.

The first storage node contact 520a may extend upward to a level L1. The second metal contact 630 may extend upward to a level L7. The hard mask 650 may extend from a level L3 up to a level L4, wherein the level L3 is substantially the same as or higher than the level L7.

The second storage node contact 520b may extend down to a level L4 to be coupled to the first storage node contact 510a, and extend up to a level L6. The level L6 may be the same as the level L2. The fourth metal contact 670 may extend down to a level L5 which is lower than or substantially the same as the level L1.

FIG. 3 is a cross-sectional view illustrating a semiconductor device according to a second embodiment of the present invention. The device shown in FIG. 3 can be formed in the same way as the method shown in FIGS. 2a-2o, except skipping the step of forming the interlayer insulating pad 552 shown in FIG. 2j. The device shown in FIGS. 2a-2o is more preferred to the device shown in FIG. 3 since the interlayer insulating pad 552 may contribute to create a hydrogen path between the first and the second interlayer insulating layers 550a, 550b and thus can enhance device performance.

According to the present invention, due to the peri-hard mask 650, a step for forming the second storage node contact 520b in the cell region and a step of forming the third and the fourth metal contacts 660, 670 in the peripheral region can be performed simultaneously, thus simplifying fabricating process and reducing product cost.

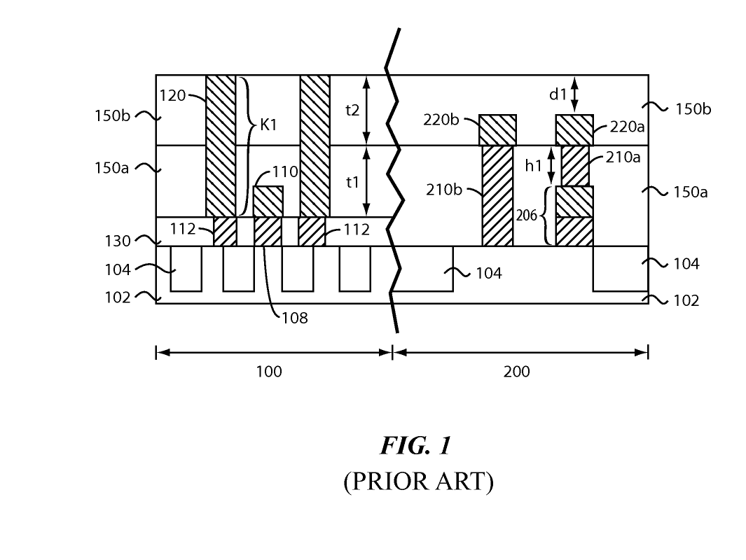

Second, the length K2, K3, a sum of thicknesses of the first and the second storage node contacts 520a, 520b, can be shortened compared to the conventional device shown in FIG. 1. In the present invention, upper surfaces of the third and the fourth metal contacts 660, 670 in the peripheral region are formed at substantially the same level L2 as an upper surface of the second storage node contact 520b in the cell region. Thus, the second interlayer insulating layer 550b can be formed shorter than the conventional device shown in FIG. 1, thus reducing the total length K2, K3 of the first and the second storage node contacts 520a, 520b. As a result, a fabrication process can be performed more precisely.

Third, a length H1, H2 of the second metal contact 630 can be formed longer than the length h1 of the first peri-metal contact 210a of the conventional device shown in FIG. 1.

When the second interlayer insulating layer 550b can be formed shorter, the length H1, H2 of the second metal contact 630 can be formed longer without increasing the total length K2, K3 of the first and the second storage node contacts 520a, 520b . Thus, a cross-talk between the peri-gate 606 and the fourth metal contact 670.

The present invention can be applied to a semiconductor device including any of a dynamic random access memory(DRAM), a resistant random access memory (ReRAM), a ferroelectric random access memory (FeRAM), a phase change RAM (PRAM), a magnetic RAM (MRAM), a spin transfer torque-magnetic RAM (STT-RAM), a zero-capacitor RAM (ZRAM), and a combination thereof

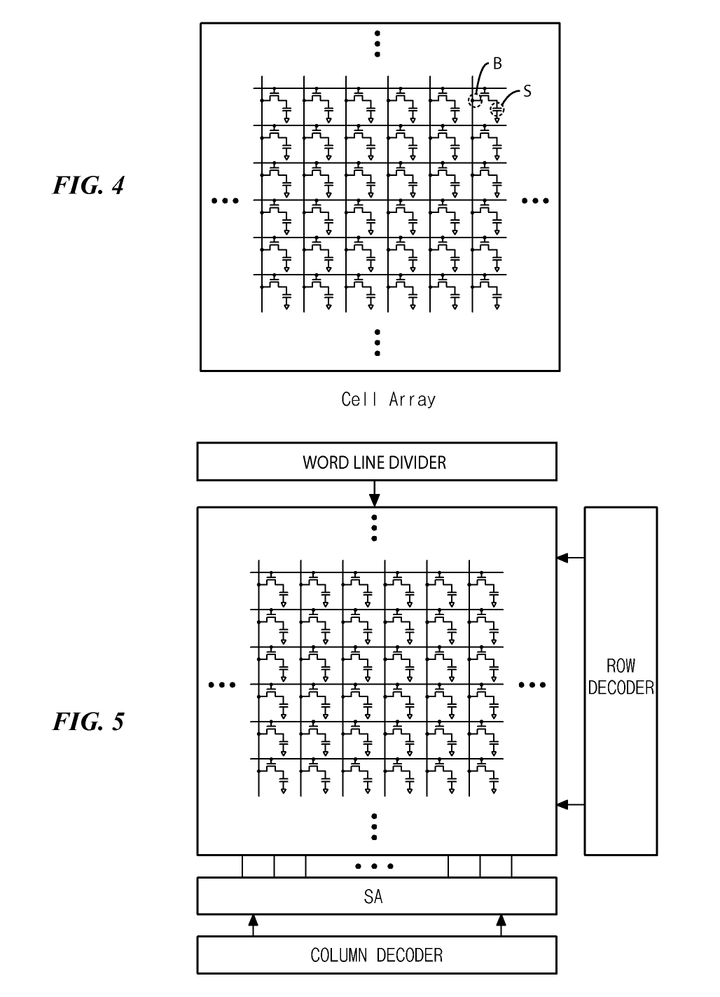

FIGS. 4-7 show semiconductor memory devices employing the structure according to an embodiment of the present invention.

FIG. 4 is a circuit diagram of a memory cell array according to an embodiment of the present invention. The memory cell array may include bit lines (B) and storage nodes (S) coupled to the bit lines (B) through a cell gate.

As shown in FIG. 4, in the memory cell array, the bit lines (BL1, . . . , BLn) are formed to extend in a first direction (or “bit line direction”), and the word lines (WL 1, . . . WLm) are formed to extend in a second direction (or “word line direction”), so that they are arranged to intersect with each other. A first terminal (e.g., drain) of the transistor is coupled to the bit lines (BL1, . . . , BLn), a second terminal (e.g., source) of the transistor is coupled to a capacitor, and a third terminal (e.g., gate) of the transistor is coupled to the word lines (WL1, . . . , WLm). The plurality of memory cells including the bit lines (BL1, . . . , BLn) and the word lines (WL1, . . . , WLm) are located in the semiconductor memory cell array.

FIG. 5 is a block diagram of a functional unit employing the memory cell array shown in FIG. 4. A row decoder and a word line driver are configured to select the cell gates. A column decoder is configured to select the bit lines (B). A sense amplifier (SA) is configured to sense data transmitted to/from the bit lines (B).

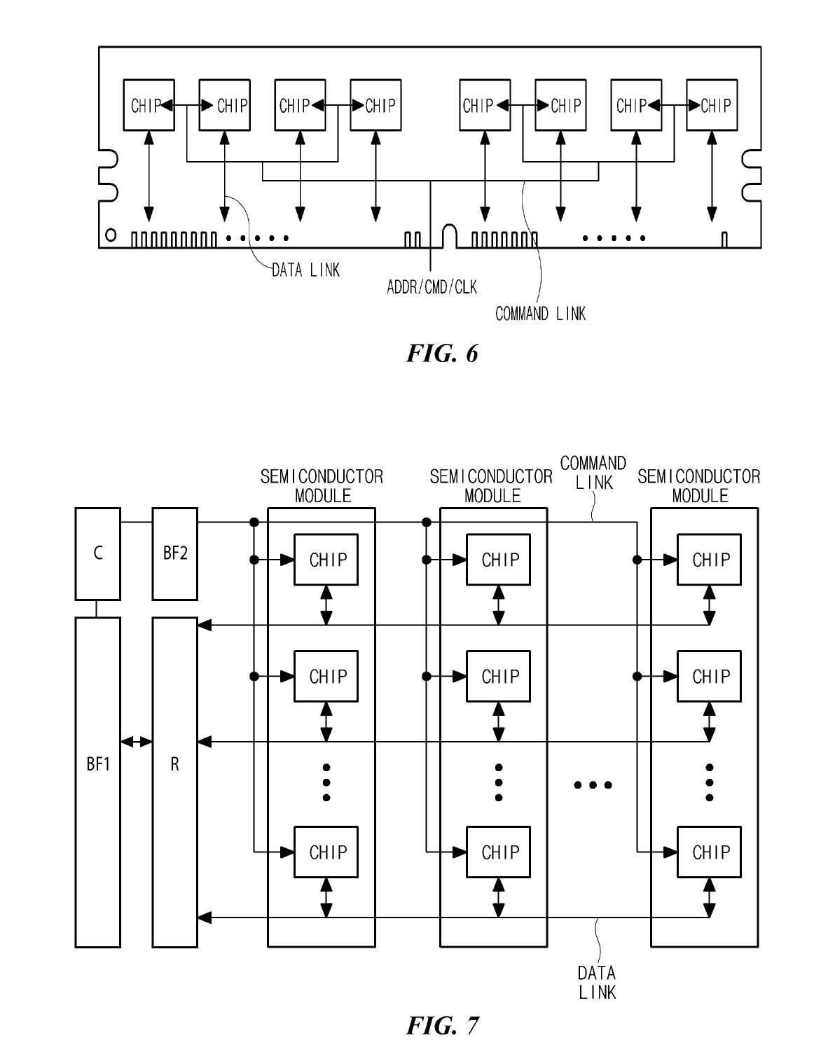

FIG. 6 is a block diagram of a memory module employing the module shown in FIG. 5. The memory module comprises a plurality of semiconductor devices mounted on a module substrate, a command link for enabling the semiconductor device to receive a control signal (address signal (ADDR)), a command signal (CMD) and a clock signal (CLK) and a data link for transmitting data connected to the semiconductor device.

FIG. 7 is a block diagram of a memory system employing the module shown in FIG. 6. The memory system includes a plurality of memory modules and a controller for communicating with the memory module through a system bus to exchange data and a command/address signal.

A data input/output buffer (BF1) is coupled to the sense amplifier, a command/address input/output buffer (BF2) is coupled to any of the column decoder and the row decoder, and a resistor (R) couples the data input/output buffer to the sense amplifier (SA). A memory controller (C) may be coupled to any of the row decoder and the column decoder.

Generally, a memory cell array comprises a plurality of memory cells each including one transistor and one capacitor. Such memory cells are located at intersections of bit lines (BL1, . . . , BLn) and word lines (WL1, . . . , WLm). The memory cells are configured to store or output data depending on voltages applied to the bit lines (BL1, . . . , BLn) and the word lines (WL1, . . . , WLm) selected by a column decoder and a row decoder, respectively.

The command link and the data link may be the same or similar to those used in a conventional semiconductor module. Although FIG. 6 shows that eight chips are mounted on the front surface of the module substrate, additional chips can be mounted on the rear surface of the module substrate in the same manner. Alternatively, additional chips can be mounted on a back side of the module substrate, and the number of chips mounted is not limited.

The memory device according to an embodiment of the present invention may be applied to dynamic random access memories (DRAMs), or synchronous dynamic random access memories (DRAMs), but it is not limited thereto. It may be applied to static random access memories (SRAMs), flash memories, ferroelectric random access memories (FeRAMs), magnetic random access memories (MRAMs), or phase change random access memories (PRAMs).

The memory device can be used, for example, in desktop computers, portable computers, computing memories used in servers, graphics memories having various specs, and mobile electronic devices as technology continues to evolve. Further, the above-described semiconductor device may be provided to various digital applications such as mobile recording mediums including a memory stick, multimedia card (MMC), secure digital (SD), compact flash (CF), extreme digital (xD) picture card, and a universal serial bus (USB) flash device as well as various applications such as MP3P, portable multimedia player (PMP), a digital camera, a camcorder, and a mobile phone. A semiconductor device may be applied to a technology such as multi-chip package (MCP), disk on chip (DOC), or embedded device. The semiconductor device may be applied to a CMOS image sensor to be provided to various fields such as a camera phone, a web camera, and a small-size image capture device for medicine.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

1-17. (canceled)

18. A semiconductor device, comprising:
a first interlayer insulating layer in first and second regions of a semiconductor substrate;
a second interlayer insulating layer (550b) over the first interlayer insulating layer in first and second regions;
a hard mask provided between the first and the second interlayer insulating layers in the second region and not extending to the first region;
a first metal contact formed through the second interlayer insulating layer and the hard mask in the second region; and
a first storage node contact formed through the first interlayer insulating layer in the first region.

19. The device of claim 18,
wherein a top surface of the a first metal contact is substantially at the same level as a top surface of the first storage node contact, and
wherein a top surface of the first metal contact is substantially at the same level as a top of the second interlayer insulating layer.

20. The device of claim 18,
wherein a bottom of the first metal contact is at a higher level than a bottom of the first storage node contact.

21. The device of claim 18, the device further comprising:
an interlayer insulating pad formed (i) between the first interlayer insulating layer and the hard mask in the second region and (ii) between the first and the second interlayer insulating layers in the first region.

22. The device of claim 21, the device further comprising:
a second metal contact formed through the first interlayer in the second region and coupled to the first metal contact; and
a second storage node contact formed through the first interlayer in the first region and coupled to the first storage node contact.

23. The device of claim 22,
wherein the second metal contact is coupled to a gate in the second region.

24. The device of claim 23,
wherein the gate in the second region is a peri-gate in a planar type.

25. The device of claim 21,
wherein the second metal contact is formed through the interlayer insulating pad in the second region, and
wherein a top of the second metal contact is at a higher level than a top of the second storage node contact.

26. The device of claim 25,
wherein the first storage node contact (520b) is formed through the interlayer insulating pad.

27. The device of claim 21,
wherein the hard mask pattern has an etch rate different from the interlayer insulating pad.

28. The device of claim 18, the device further comprising:
a first gate formed in the first region,
wherein the first gate is any of a buried gate, a recess gate, and a planar gate.

29. The device of claim 18,
wherein the semiconductor device is any of a dynamic random access memory(DRAM), a resistant random access memory (ReRAM), a ferroelectric random access memory (FeRAM), a phase change RAM (PRAM), a magnetic RAM (MRAM), a spin transfer torque-magnetic RAM (STT-RAM), a zero-capacitor RAM (ZRAM), and a combination thereof, and
wherein the first region is a cell region and the second region is a peripheral region.

30. The device of claim 18,
wherein the hard mask pattern includes plasma enhanced nitride.

31. The device of claim 18,
wherein the hard mask pattern has an etch rate different from the first interlayer insulating layer.

32. The device of claim 18,
wherein the first contact and the first metal contact are formed of the same conductive material.

33. The device of claim 32,
wherein the first contact and the first metal contact includes tungsten.

34. A semiconductor device, comprising:
a first storage node contact formed in a first region of a semiconductor substrate and extending upward to a first level;
a first metal contact formed in a second region of the semiconductor substrate, coupled to a gate in the second region, and extending upward to a second level;
a hard mask formed in the second region and not extending to the peripheral region, wherein the hard mask extends from a third level up to a fourth level, wherein the third level is substantially the same as or higher than the second level;
a second storage node contact formed in the first region, extending down to a fifth level to be coupled to the first storage node contact, and extending up to a sixth level; and
a second metal contact formed in the second region, extending down to a seventh level to be coupled to the first metal contact, and extending up to the sixth level.

35. The semiconductor device of claim 34,
wherein the second level is higher than or substantially the same as the first level.

36. The semiconductor device of claim 34,
wherein the second level and the third level are substantially the same.

37. The semiconductor device of claim 34,
wherein the seventh level is higher than or substantially the same as the fifth level.

38. The semiconductor device of claim 34,
wherein the first storage node and the first metal contact are formed through a first interlayer insulating layer,
wherein the second storage node and the second metal contact are formed through a second interlayer insulating layer, wherein the second interlayer insulating layer is provided over the first interlayer insulting layer,
wherein the hard mask is formed between the first and the second interlayer insulating layers in the second region and does not extend to the first region, and
wherein the second metal contact is formed through the hard mask.

39. The semiconductor device of claim 38, the semiconductor device further comprising:
an interlayer insulating pad formed (i) between the first interlayer insulating layer and the hard mask in the second region and (ii) between the first and the second interlayer insulating layers in the first region,
wherein the second storage node contact is formed through the interlayer insulating pad in the first region, and
wherein, the first metal contact is formed through the interlayer insulating pad in the second region.

40-43. (canceled)
